(19) United States
(12) Patent Application Publication
(10) Pub. No.: US 2007/0198905 A1
(43) Pub. Date: Aug. 23, 2007

(54) Transmitter for a communications network

(75) Inventors: Tejas Bhatt, Irving, TX (US); Amitabh Dixit, Dallas, TX (US); Victor Stolpman, Dallas, TX (US)

Correspondence Address: SQUIRE, SANDERS & DEMPSEY L.L.P., 14TH FLOOR, 8000 TOWERS CRESCENT, TYSONS CORNER, VA, 22182, US

(73) Assignee: NOKIA CORPORATION

(21) Appl. No.: 11/346,184

(22) Filed: Feb. 3, 2006

(51) Int. Cl. G06F 11/00; H03M 13/00

(52) U.S. Cl. 714/801

(57) ABSTRACT

A transmitter for a communications network, the transmitter comprising: receiving means for receiving data; accessing means for accessing a parity check code; generating means for generating encoded data including an error correction codeword using the data and the parity check code; and transmitting means for transmitting the encoded data and the error correction codeword,
wherein the parity check code comprises a parity check matrix which, in expanded form, can be represented by the matrix H having the general structure

$$( \begin{matrix}A & B & T \\ C & D & E\end{matrix} ) `$$

wherein A, B, T, C, D and E represent sub-matrices, ET⁻¹B being equal to the null matrix, the generating means comprising summing circuitry arranged to receive matrix elements ET⁻¹A and C to generate a sum, and matrix multiplication circuitry for receiving the sum, a matrix element D⁻¹ and a matrix s^{T} comprising the data, the matrix multiplication circuitry being operable to generate a parity part p₁^{T} of the error correction codeword according to the formula
p₁^{T}=−D⁻¹(−ET⁻¹A+C)s^{T}.

### FIELD OF INVENTION

The present invention relates to a transmitter for a communications network and a method of transmitting data in a communications network.

### BACKGROUND OF THE INVENTION

Modern communication systems use Forward Error Correction (FEC) codes in an attempt to convey information more reliably through channels with random events. One such FEC error control system uses low density parity check (LDPC) codes. LDPC codes can have error correcting capabilities that rival the performance of “Turbo-Codes” and can be applicable over a wide range of statistical channels.

Low-Density parity check (LDPC) codes are a class of linear block codes, which provide near-capacity performance on a large set of data transmission and storage channels. These codes have proven to be serious competitors to turbo codes in terms of their error correcting performance. Also, LDPC codes exhibit an asymptotically better performance than turbo codes and also admit a better trade-off between performance and decoding complexity.

By taking into account the density evolution of messages passed in belief propagation decoding, random constructions of irregular LDPC codes can be developed that approach Shannon limits for an assortment of channels (e.g. Additive White Gaussian Noise (AWGN), Binary Erasure Channel (BEC), Binary Symmetric Channel (BSC)). These are typically described as ensembles with variable and check edge polynomials

$$λ ( x ) = {\sum }_{i = 2}^{{d}_{l}} {λ}_{i} {x}^{i - 1} and ρ ( x ) = {\sum }_{j = 2}^{{d}_{r}} {ρ}_{j} {x}^{j - 1} ,$$

respectively, where λᵢ and ρⱼ are the fraction of total edges connected to variable and check nodes of degree i=2, 3, . . . , d₁ and j=2, 3, . . . , dᵣ respectively.

Thus, some random irregular LDPC constructions based upon edge ensemble designs have error correcting capabilities measured in Bit Error Rate (BER) that are within 0.05 dB of the rate-distorted Shannon limit. Unfortunately, these LPDC code constructions often require long codeword constructions (on the order of 10⁶ to 10⁷ bits) in order to achieve these error rates. Despite good BER performance, these random code constructions often have poor Block Error Rate (BLER) performances required by packet-based communication systems. Therefore, these random constructions typically do not lend themselves well to packet-based communication systems. In actual communication terminals, these random constructions can require storage of the entire parity-check matrix, and for systems employing variable packet-length, the storage of multiple random constructions is both necessary and costly.

Another disadvantage of random constructions based on edge distribution ensembles is that, for each codeword length, a separate random construction is needed. Thus, communication systems employing variable block sizes (e.g. TCP/IP systems) require multiple code definitions. Such multiple code definitions can consume a significant amount of non-volatile memory for large combinations of codeword lengths and code rates.

As an alternative to random LDPC constructions, structured LDPC constructions typically rely on a general algorithmic approach to constructing LDPC matrices which often requires much less non-volatile memory than random constructions. One such structured approach is based upon array codes. This approach can exhibit improved error performance (both BER and BLER performance) and a relatively low error floor for relatively high code rates (higher than 0.85). However, for code rates below 0.85, these code constructions have relatively poor performance with respect to irregular random constructions designed for lower code rates. One reason for this poor performance can be that their constructions are typically based on code ensembles that have poor asymptotic performances despite being an irregular construction.

One challenge therefore is to design irregular structured LDPC codes that have good overall error performance for a wide range of code rates with attractive storage requirements. Such resulting LDPC codes would provide a better performing communication system with lower cost terminals. These factors can make such FEC attractive for applications over a wide range of products, including but not limited to, wireless LAN systems, next generation cellular systems, and ultra wide band systems.

With all the advantages that LDPC codes offer, one major criticism concerning LDPC codes has been their high encoding complexity. Whereas turbo codes can be encoded in linear time, a straightforward encoder implementation of LDPC codes has complexity quadratic in the block length.

Recently, new means of constructing LDPC codes have emerged as described by V. Stolpman in “Irregular Structured Low-Density Parity-Check (LDPC) Codes” a recently filed US patent application claiming priority from U.S. Patent Application No. 60/599,283, filed Aug. 6, 2004, V. Stolpman, J. Zhang, N. van Waes, “Irregular Structured Low-Density Parity-Check (LDPC) Codes,” document submitted to IEEE802.16 ad hoc group, Aug. 6, 2004, and P. Joo, et al., “LDPC coding for OFDMA PHY,” IEEE C802.16d-04/86r1, http://ieee802.org/16, May 2004 (the first two references are hereinafter referred to as V. Stolpman et al). Irregular structured codes based on a shifted identity matrix have gained increasing popularity due to reduced storage and ease of decoder implementation

These consist of using smaller “seed” matrices to be expanded into larger parity-check matrices using a set of “spreading” permutation matrices. The seed matrices can be small binary matrices to be used with a rule-based exponential to select the spreading permutation matrices that construct sub-matrices within the expanded LDPC matrix, or seed matrices may consist of exponentials that define the shift indices of the sub-matrices within the expanded LDPC matrix. Benefits associated with these structured LDPC codes include all the advantages of a modular code-construction approach along with the possibility of layered belief propagation decoding that allows for implementations that speed convergence time and reduce the number of iterations (see, for example, M. M. Mansour and N. R. Shanbhag, “Turbo decoder architectures for low-density parity check codes,” IEEE Global Comm. Conf. (GLOBECOM), November 2002, pp. 1383-1388; M. M. Mansour and N. R. Shanbhag, “Low power VLSI architectures for LDPC codes,” in 2002 International Low Power Electronics and Design, 2002, pp. 284-289; D. E. Hocevar, “LDPC code construction with flexible hardware implementation,” Proc.: IEEE Int'l Conf. On Comm. (ICC), Anchorage, Ak., May 2003; and M. M. Mansour and N. R. Shanbhag, “High-Throughput LDPC Decoders,” IEEE Trans. On VLSI Systems, vol. 11, No. 6, pp. 976-996, December 2003).

A novel encoding approach has been proposed by T. J. Richardson, and R. L. Urbanke, “Efficient Encoding of Low-Density Parity-Check Codes,” IEEE Transactions on Information Theory, vol. 47, pp. 638-656, February 2001 (hereinafter referred to as Richardson and Urbanke), which greatly reduces the encoding complexity of the LDPC codes by first bringing the LDPC parity check matrix into an approximate lower triangular form and then exploiting the structure of this transformed parity check matrix to achieve near linear encoding complexity.

The encoding algorithm proposed by Richardson and Urbanke reduces the encoding complexity for LDPC codes from quadratic to near linear complexity. It was shown by Richardson and Urbanke that the encoding complexity is upper bounded by (n+g²) where n is the code length and g is a measure of the “distance” between the LDPC parity check matrix and a lower triangular matrix.

There is an on going need design transmitters for communications networks which are reduced in complexity in terms of their hardware, which are reduced in complexity in terms of their software, and which are highly efficient at encoding and transmitting data at high rates with low errors. Such transmitters have been previously designed to utilize the aforementioned encoding algorithms. However, these transmitters are still too complex. It is therefore an aim of the present invention to provide a transmitter which is reduced in complexity compared to previous transmitters in terms of both hardware and software, and which is more efficient at encoding and transmitting data at high rates with low errors.

### SUMMARY OF THE INVENTION

According to a first aspect of the present invention there is provided a transmitter for a communications network, the transmitter comprising: receiving means for receiving data; accessing means for accessing a parity check code; generating means for generating encoded data including an error correction codeword using the data and the parity check code; and transmitting means for transmitting the encoded data and the error correction codeword, wherein the parity check code comprises a parity check matrix which, in expanded form, can be represented by the matrix H having the general structure

$$( \begin{matrix}A & B & T \\ C & D & E\end{matrix} )$$

wherein A, B, T, C, D and E represent sub-matrices, ET⁻¹B being equal to the null matrix, the generating means comprising summing circuitry arranged to receive matrix elements ET⁻¹A and C to generate a sum, and matrix multiplication circuitry for receiving the sum, a matrix element D⁻¹ and a matrix s^{T} comprising the data, the matrix multiplication circuitry being operable to generate a parity part p₁^{T} of the error correction codeword according to the formula
p₁^{T}=−D⁻¹(−ET⁻¹A+C)s^{T}.

According to another aspect of the present invention there is provided a method of transmitting data in a communications network, the method comprising the steps of: receiving data; accessing a parity check code; generating encoded data including an error correction codeword using the data and the parity check code; and transmitting the encoded data and the error correction codeword, wherein the parity check code comprises a parity check matrix which, in expanded form, can be represented by the matrix H having the general structure

$$( \begin{matrix}A & B & T \\ C & D & E\end{matrix} )$$

wherein A, B, T, C, D and E represent sub-matrices and where ET⁻¹B is equal to the null matrix, the step of generating the error correction codeword including supplying selected elements of the matrix H to logic circuitry which includes summing circuitry for summing matrix elements ET⁻¹A and C to generate a sum and matrix multiplication circuitry for receiving the sum, the matrix element D⁻¹ and a matrix s^{T} comprising the data thereby to generate a parity part p₁^{T} according to the formula
p₁^{T=-D}⁻¹(−ET⁻¹A+C)s^{T}.

Embodiments of the present invention are designed to use a new class of irregular structured LDPC codes based on those disclosed by V. Stolpman et al and exploiting the encoder structure disclosed by Richardson and Urbanke to achieve reduction in encoding complexity without sacrificing performance. Embodiments of the present invention are based upon the observation that the structured LDPC codes proposed by V. Stolpman et al have an even stronger structure than is assumed by Richardson and Urbanke. In particular, the previous codes have been simplified by modifying them such that ET⁻¹B is equal to the null matrix. Such a modification has enabled the present inventors to design a new transmitter arrangement which is reduced in complexity compared to previous transmitters in terms of both hardware and software, and which is more efficient at encoding and transmitting data at high rates with low errors.

The reduction in complexity is achieved by effectively reducing the number of matrix multiplications required to generate the code and reduce the number of matrix multiplications required to use the code in order to generate codewords. The matrices involved in the multiplications may have a size of the order 108×108, for example. By avoiding multiplications involving large matrices, processing time is reduced.

Furthermore, the hardware for implementing the code may also be simplified by reducing the number of XOR and AND gates required for binary matrix multiplication (for example, by a few hundred ASIC gates). Embodiments of the present invention can lead to an approximately 20% reduction in terms of hardware area.

According to another aspect of the present invention there is provided a parity check code comprising a parity check matrix which, in expanded form, can be represented by the matrix H having the general structure

$$( \begin{matrix}A & B & T \\ C & D & E\end{matrix} )$$

wherein A, B, T, C, D and E represent sub-matrices and wherein ET⁻¹B is equal to the null matrix.

Preferably, the code comprises a seed matrix H_{SEED} and a spreading matrix P_{SPREAD}. Further reduction in complexity is achieved by operating at the seed matrix level without expanding to the full parity check matrix.

According to another aspect of the present invention there is provided an electronic device, comprising: a processor; and a memory unit operative connected to the processor and including the parity check code described above.

According to another aspect of the present invention there is provided a communications system comprising a transmitter and a receiver, and including the parity check code described above for encoding and transmitting data between the transmitter and receiver.

According to another aspect of the present invention there is provided a network element comprising the parity check code described above.

According to another aspect of the present invention there is provided a computer program product comprising the parity check code described above.

According to another aspect of the present invention there is provided a method of generating an error correction code, the method comprising: providing a parity check matrix which, in expanded form, can be represented by the matrix H having the general structure

$$( \begin{matrix}A & B & T \\ C & D & E\end{matrix} )$$

wherein A, B, T, C, D and E represent sub-matrices; and modifying H wherein ET⁻¹B is equal to the null matrix.

According to another aspect of the present invention there is provided a method of generating an error correction codeword using a parity check code as described above, wherein the error correction codeword x comprises a systematic parts and parity parts p₁ and p₂, parity parts p₁ and p₂ being computed as follows: p₁^{T}=−φ⁻¹(−ET⁻¹A+C)s^{T}, and p₂^{T}=−T⁻¹(As^{T}+Bp₁^{T}), where φ=−ET⁻¹B+D and ET⁻¹B is equal to the null matrix whereby φ is equal to D.

Embodiments of the present invention utilize a novel method of processing the LDPC code matrix which is more efficient than prior art methods. The inverted matrices ^{φ-1} and T⁻¹ used to calculate the parity parts of the codeword can be pre-calculated and stored in a memory. Therefore, a device does not necessarily have to use the efficient calculation methods for forming these matrices. However, the resultant LDPC codes will have the characteristic that ET⁻¹B is a null matrix and this requirement is used for simplifying the calculations.

Embodiments of the present invention may require hardware components (and possible software components) in both the transmitter and receiver. The transmitter facilitates the encoding of the LDPC code, and the receiver decodes the LDPC code after transmission through a channel.

Embodiments of the present invention provide for an irregularly structured LDPC code ensemble that has strong overall error performance and attractive storage requirements for a large set of codeword lengths. Embodiments of the invention offer communication systems with better performance and lower terminal costs due to the reduction in mandatory non-volatile memory over conventional systems.

These and other objects, advantages and features of the invention, together with the organization and manner of operation thereof, will become apparent from the following detailed description when taken in conjunction with the accompanying drawings, wherein like elements have like numerals throughout the several drawings described below.

### BRIEF DESCRIPTION OF THE DRAWINGS

FIG. 1 is an overview diagram of a system within which embodiments of the invention may be implemented;

FIG. 2 is a perspective view of a mobile telephone that can be used in the implementation of one embodiment the present invention;

FIG. 3 is a schematic representation of the telephone circuitry of the mobile telephone of FIG. 2;

FIG. 4 is a flow chart showing the implementation of one embodiment of the present invention;

FIG. 5 is a schematic diagram of a transmitter not according to the present invention;

FIG. 6 is a schematic diagram of a transmitter according to an embodiment of the present invention;

FIG. 7 presents the comparative bit error rate (BER) performance and codeword error rate (CER) performance in AWGN environment of the original LDPC code and the modified LDPC code such that φ is a permutation matrix for the LDPC code of block length 72 bytes and rate ½;

FIG. 8 presents the comparative BER and CER performance in AWGN environment of the original LDPC code and the modified LDPC code such that φ is a permutation matrix for the LDPC code of block length 72 bytes and rate ⅔;

FIG. 9 presents the comparative BER and CER performance in AWGN environment of the original LDPC code and the modified LDPC code such that φ is a permutation matrix for the LDPC code of block length 72 bytes and rate ¾;

FIG. 10 presents the comparative BER and CER performance in AWGN environment of the original LDPC code and the modified LDPC code such that φ is a permutation matrix for the LDPC code of block length 90 bytes and rate ½;

FIG. 11 presents the comparative BER and CER performance in AWGN environment of the original LDPC code and the modified LDPC code such that φ is a permutation matrix for the LDPC code of block length 90 bytes and rate ⅔;

FIG. 12 presents the comparative BER and CER performance in AWGN environment of the original LDPC code and the modified LDPC code such that φ is a permutation matrix for the LDPC code of block length 90 bytes and rate ¾; and

FIG. 13 presents the comparative BER and CER performance in AWGN environment of the original LDPC code and the modified LDPC code such that φ is a permutation matrix for the LDPC code of block length 144 bytes and rate ½.

### DETAILED DESCRIPTION OF THE PREFERRED EMBODIMENTS

Various exemplary embodiments of the invention are described below with reference to the drawing figures. One embodiment of the invention can be described in the general context of method steps, which may be implemented in one embodiment by a program product including computer-executable instructions, such as program code, executed by computers in networked environments. Embodiments of the invention may be implemented in either hardware or software, and can be placed within a transmitter and/or a receiver.

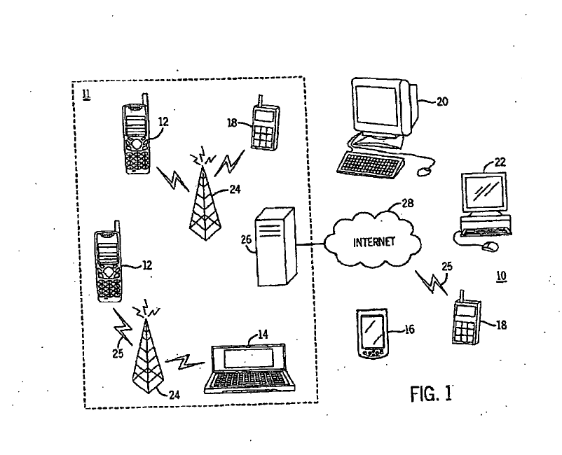

FIG. 1 shows a system 10 illustrating one embodiment of the invention, comprising multiple communication devices that can communicate through a network. The system 10 may comprise any combination of wired or wireless networks including, but not limited to, a mobile telephone network, a wireless Local Area Network (LAN), a Bluetooth personal area network, an Ethernet LAN, a token ring LAN, a wide area network, the Internet, etc. The system 10 may include both wired and wireless communication devices.

For exemplification, the system 10 shown in FIG. 1 can include a mobile telephone network 11 and the Internet 28. Connectivity to the Internet 28 may include, but is not limited to, long range wireless connections, short range wireless connections, and various wired connections including, but not limited to, telephone lines, cable lines, power lines, and the like.

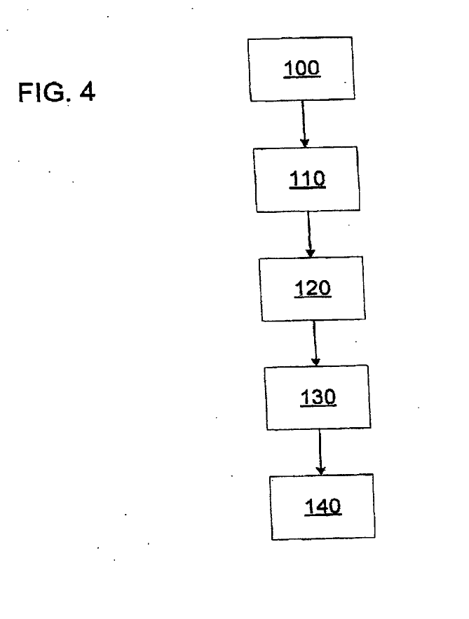

Exemplary communication devices of the system 10 may include, but are not limited to, a mobile telephone 12, a combination PDA and mobile telephone 14, a PDA 16, an integrated messaging device (IMD) 18, a desktop computer 20, and a notebook computer 22. The communication devices may be stationary or mobile as when carried by an individual who is moving. The communication devices may also be located in a mode of transportation including, but not limited to, an automobile, a truck, a taxi, a bus, a boat, an airplane, a bicycle, a motorcycle, etc. Some or all of the communication devices may send and receive calls and messages and communicate with service providers through a wireless connection 25 to a base station 24. The base station 24 may be connected to a network server 26 that allows communication between the mobile telephone network 11 and the Internet 28. The system 10 may include additional communication devices and communication devices of different types. A communication device may communicate using various media including, but not limited to, radio, infrared, laser, cable connection, and the like. One such portable electronic device incorporating a wide variety of features is shown in FIG. 4. This particular embodiment may serves as both a video gaming device and a portable telephone.

The communication devices may communicate using various transmission technologies including, but not limited to, Code Division Multiple Access (CDMA), Global System for Mobile Communications (GSM), Universal Mobile Telecommunications System (UMTS), Time Division Multiple Access (TDMA), Frequency Division Multiple Access (FDMA), Transmission Control Protocol/Internet Protocol (TCP/IP), Short Messaging Service (SMS), Multimedia Messaging Service (MMS), e-mail, Instant Messaging Service (IMS), Bluetooth, IEEE 802.11, etc.

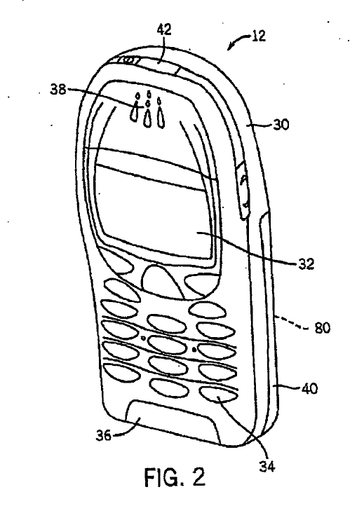

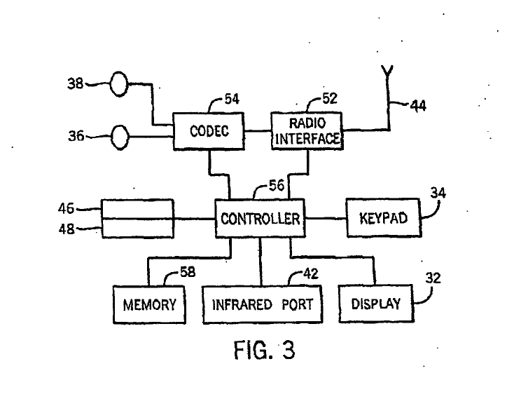

FIGS. 2 and 3 show one representative mobile telephone 12 within which one embodiment of the present invention may be implemented. It should be understood, however, that the present invention is not intended to be limited to one particular type of mobile telephone 12 or other electronic device. The mobile telephone 12 of FIGS. 2 and 3 comprises a housing 30, a display 32 in the form of a liquid crystal display, a keypad 34, a microphone 36, an ear-piece 38, a battery 40, an infrared port 42, an antenna 44, a smart card 46 in the form of a universal integrated circuit card (UICC) according to one embodiment of the invention, a card reader 48, radio interface circuitry 52, codec circuitry 54, a controller 56 and a memory 58.

Generally, program modules can include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps.

Software and web implementations of the present invention could be accomplished with standard programming techniques with rule-based logic and other logic to accomplish the various database searching steps, correlation steps, comparison steps and decision steps. It should also be noted that the words “component” and “module” as used herein, and in the claims, are intended to encompass implementations using one or more lines of software code, and/or hardware implementations, and/or equipment for receiving manual inputs.

Constructing an LDPC Matrix H

As discussed in V. Stolpman et al, an irregular “seed” parity-check matrix can be used as the “seed” for irregular structured LDPC code. In one arrangement, the construction of an irregular “seed” low-density parity check-matrix H_{SEED} of dimension ((N_{SEED}−K_{SEED})×N_{SEED}) is derived from an edge distribution, λ_{SEED}(x) and ρ_{SEED}(x), with good asymptotic performance and good girth properties. Good asymptotic performance may be characterized by a good threshold value using belief propagation decoding and good girth may be characterized by having very few if no variable nodes with a girth of 4. This can be accomplished manually or via a software program once given the code ensemble and/or node degrees.

Although there are no limits on the maximum values of K_{SEED} and N_{SEED}, which represent the number of information bits and the resulting codeword length, respectively, for the code defined by H_{SEED}, these values can be relatively small in comparison to the target message-word and codeword length. This can allow for more potential integer multiples of N_{SEED} within the target range of codeword lengths, reduced storage requirements, and simplified code descriptions. In one arrangement, the smallest possible value for H_{SEED} can be used with edge distributions defined by λ_{SEED}(x) and ρ_{SEED}(x), while still maintaining good girth properties.

One function of the seed matrix can be to identify the location and type of sub-matrices in the expanded LDPC parity-check matrix H constructed from H_{SEED} and a given set of permutation matrices. The permutation matrices in H_{SEED} can determine the location of sub-matrices in the expanded matrix H that contain a permutation matrix of dimension (N_{SPREAD}×N_{SPREAD}) from the given set. One selection within the given set of permutation matrices is defined below. As an example only, the given set of permutation matrices used herein can be finite and consist of the set

{P_{SPREAD}^{∞}, P_{SPREAD}⁰, P_{SPREAD}¹, P_{SPREAD}², . . . , P_{SPREAD}^{p-1}}
where p is a positive integer (a prime number in a preferred embodiment of the invention), P_{SPREAD}⁰=I is the identity matrix, P_{SPREAD}¹ is a full-rank permutation matrix, P_{SPREAD}²=P_{SPREAD}¹P_{SPREAD}¹, etc. up to P_{SPREAD}^{p-1}. One example embodiment of P_{SPREAD}¹ is a single circular shift permutation matrix

$${P}_{SPREAD}^{1} = [ \begin{matrix}0 & 1 & 0 & 0 & 0 \\ 0 & 0 & 1 & 0 & 0 \\ 0 & 0 & 0 & 1 & 0 \\ 0 & 0 & 0 & 0 & 1 \\ 1 & 0 & 0 & 0 & 0\end{matrix} ] for {N}_{SPREAD} = 5$$

Another example embodiment of P_{SPREAD}¹ is an alternate single circular shift permutation matrix

$${P}_{SPREAD}^{1} = [ \begin{matrix}0 & 0 & 0 & 0 & 1 \\ 1 & 0 & 0 & 0 & 0 \\ 0 & 1 & 0 & 0 & 0 \\ 0 & 0 & 1 & 0 & 0 \\ 0 & 0 & 0 & 1 & 0\end{matrix} ] for {N}_{SPREAD} = 5.$$

For notational sake, P_{SPREAD}^{∞} denotes the all zeros matrix φ of dimension (N_{SPREAD}×N_{SPREAD}) (i.e. P_{SPREAD}^{∞}=0 where every element is a zero), and the zeros in H_{SEED} indicate the location of the sub-matrix P_{SPREAD}^{∞}=0 in the expanded matrix H. Thus, the expanded LDPC matrix H can be of dimension (N_{SPREAD}(N_{SEED}−K_{SEED})×N_{SPREAD}N_{SEED}) with sub-matrices consisting of permutation matrices of dimension (N_{SPREAD}×N_{SPREAD}) raised to an exponential power from the set of {0, 1, . . . , p−1, ∞}.

Furthermore, the expanded LDPC code can have the same edge distribution as H_{SEED} and hence can achieve the desired asymptotic performance described by λ_{SEED}(x) and ρ_{SEED}(x), provided both H_{SEED} and the expanded matrix H have satisfactory girth properties.

The following description concerns one arrangement that constructs a structured array exponent matrix that may be described as

$${E}_{ARRAY} = [ \begin{matrix}{E}_{1 , 1} & {E}_{1 , 2} & ⋯ & {E}_{1 , p} \\ {E}_{2 , 1} & {E}_{2 , 2} & ⋯ & {E}_{2 , p} \\ ⋮ & ⋮ & ⋰ & ⋮ \\ {E}_{p , 1} & {E}_{p , 2} & ⋯ & {E}_{p , p}\end{matrix} ] , \\ where {E}_{i , j} = ( i - 1 ) ( j - 1 ) mod p$$

using modulo arithmetic (but not limited to) of a number p. In one arrangement, p can be a prime number, but this is not necessary for the principles of the present invention. p can be at least the column dimension of the irregular “seed” parity check matrix and the column dimension of the spreading permutation matrix. In one arrangement, N_{SEED}≦p and N_{SPREAD}≦p. However, other values are also possible.

Other arrangements can use transformed versions of E_{ARRAY}. In particular, one such transformation involves the shifting of rows to construct an upper triangular matrix while replacing vacated element locations with ∞, i.e.

$${E}_{SHIFT} = [ \begin{matrix}{E}_{1 , 1} & {E}_{1 , 2} & {E}_{1 , 3} & ⋯ & {E}_{1 , p} \\ ∞ & {E}_{2 , 1} & {E}_{2 , 2} & ⋯ & {E}_{2 , p - 1} \\ ∞ & ∞ & {E}_{3 , 1} & ⋯ & {E}_{3 , p - 2} \\ ⋮ & ⋮ & ⋮ & ⋰ & ⋮ \\ ∞ & ∞ & ∞ & ⋯ & {E}_{p , 1}\end{matrix} ] .$$

Another arrangement transforms E_{ARRAY} by the truncation of columns and/or rows to select a sub-matrix of E_{ARRAY} for implementation with a specified H_{SEED}. Still another arrangement uses the combination of both shifting and truncation. For example, given N_{SEED}+1≦p and N_{SPREAD}≦p (with p being a prime number in a particular arrangement)

$${E}_{TRUNCATE 1} = [ \begin{matrix}{E}_{1 , 2} & {E}_{1 , 3} & {E}_{1 , 4} & … & {E}_{1 , ( {N}_{SEED} - {K}_{SEED} )} & … & {E}_{1 , ( {N}_{SEED} + 1 )} \\ {E}_{2 , 1} & {E}_{2 , 2} & {E}_{2 , 3} & … & {E}_{2 , ( {N}_{SEED} - {K}_{SEED} - 1 )} & … & {E}_{2 , {N}_{SEED}} \\ ∞ & {E}_{3 , 1} & {E}_{3 , 2} & … & {E}_{3 , ( {N}_{SEED} - {K}_{SEED} - 2 )} & … & {E}_{3 , ( {N}_{SEED} - 1 )} \\ ⋮ & ⋮ & ⋰ & ⋰ & ⋮ & ⋰ & ⋮ \\ ∞ & ∞ & ∞ & … & {E}_{( {N}_{SEED} - {K}_{SEED} ) , 1} & … & {E}_{( {N}_{SEED} - {K}_{SEED} ) , ( {K}_{SEED} + 2 )}\end{matrix} ]$$

For N_{SEED}+2≦p and N_{SPREAD}≦p (with p being a prime number in a particular arrangement)

$${E}_{TRUNCATE 2} = [ \begin{matrix}{E}_{2 , 2} & {E}_{2 , 3} & {E}_{2 , 4} & … & {E}_{2 , ( {N}_{SEED} - {K}_{SEED} )} & … & {E}_{2 , ( {N}_{SEED} + 1 )} \\ {E}_{3 , 1} & {E}_{3 , 2} & {E}_{3 , 3} & … & {E}_{3 , ( {N}_{SEED} - {K}_{SEED} - 1 )} & … & {E}_{3 , {N}_{SEED}} \\ ∞ & {E}_{4 , 1} & {E}_{4 , 2} & … & {E}_{4 , ( {N}_{SEED} - {K}_{SEED} - 2 )} & … & {E}_{4 , ( {N}_{SEED} - 1 )} \\ ⋮ & ⋮ & ⋰ & ⋰ & ⋮ & ⋰ & ⋮ \\ ∞ & ∞ & ∞ & … & {E}_{( {N}_{SEED} - {K}_{SEED} + 1 ) , 1} & … & {E}_{( {N}_{SEED} - {K}_{SEED} + 1 ) , ( {K}_{SEED} + 2 )}\end{matrix} ] .$$

Many shift and truncate arrangements can be used, as well as column and row permutation transformations performed either prior to or after other individual transformations in a nested fashion. More generally, the transformation of the E_{ARRAY} matrix can be described using the functional notation T(E_{ARRAY}) that represents a transformed exponent matrix of dimension ((N_{SEED}−K_{SEED})×N_{SEED}). Yet another arrangement of this family of transformations may include an identity transformation. For example, in another arrangement, T(E_{ARRAY})=E_{ARRAY}.

In one arrangement H_{SEED} and T(E_{ARRAY}) can be used to construct the final exponent matrix in order to expand the seed matrix into H. The final exponent matrix may be defined as

$${F}_{FINAL} = \\ [ \begin{matrix}{F}_{1 , 1} & {F}_{1 , 2} & … & {F}_{1 , {N}_{SEED}} \\ {F}_{2 , 1} & {F}_{2 , 2} & … & {F}_{2 , {N}_{SEED}} \\ ⋮ & ⋮ & ⋰ & ⋮ \\ {F}_{( {N}_{SEED} - {K}_{SEED} ) , 1} & {F}_{( {N}_{SEED} - {K}_{SEED} ) , 2} & … & {F}_{( {N}_{SEED} - {K}_{SEED} ) , {N}_{SEED}}\end{matrix} ]$$

of dimension ((N_{SEED}−K_{SEED})×N_{SEED}) by replacing each one in H_{SEED} with the corresponding matrix element (i.e. the same row and column) in the transformed structured array exponent matrix T(E_{ARRAY}) and each zero in H_{SEED} with ∞. Thus, the elements of F_{FINAL} can belong to the set {0, 1, . . . , p−1, ∞} if modulo arithmetic is used in the construction of E_{ARRAY}.

The following is a discussion of one arrangement of the expansion of H_{SEED} using F_{FINAL} to construct a final LDPC parity-check matrix H that describes the LDPC code. The matrix H_{SEED} of dimension ((N_{SEED}−K_{SEED})×N_{SEED}) can be spread or expanded using the elements of the permutation matrix set

{P_{SPREAD}^{∞}, P_{SPREAD}⁰, P_{SPREAD}¹, P_{SPREAD}², . . . , P_{SPREAD}⁻¹}
with elements of dimension (N_{SPREAD}×N_{SPREAD}), where P_{SPREAD}^{∞}=0 is the all zeros matrix, P_{SPREAD}⁰=I is the identity matrix, P_{SPREAD}¹ is a permutation matrix, P_{SPREAD}²=P_{SPREAD}¹P_{SPREAD}¹, P_{SPREAD}³=P_{SPREAD}¹P_{SPREAD}¹P_{SPREAD}¹, etc. (but not limited to) to construct

$$H = \\ [ \begin{matrix}{P}_{SPREAD}^{{F}_{1 , 1}} & {P}_{SPREAD}^{{F}_{1 , 2}} & … & {P}_{SPREAD}^{{F}_{1 , {N}_{SEED}}} \\ {P}_{SPREAD}^{{F}_{2 , 1}} & {P}_{SPREAD}^{{F}_{2 , 2}} & … & {P}_{SPREAD}^{{F}_{2 , {N}_{SEED}}} \\ ⋮ & ⋮ & ⋰ & ⋮ \\ {P}_{SPREAD}^{{F}_{( {N}_{SEED} - {K}_{SEED} ) , 1}} & {P}_{SPREAD}^{{F}_{( {N}_{SEED} - {K}_{SEED} ) , 2}} & … & {P}_{SPREAD}^{{F}_{( {N}_{SEED} - {K}_{SEED} ) , {N}_{SEED}}}\end{matrix} ]$$

of dimension (N_{SPREAD}(N_{SEED}−K_{SEED})×N_{SPREAD N}_{SEED}). Thus, this arrangement can be used to describe an expanded LDPC code with sub-matrices of dimension (N_{SPREAD}×N_{SPREAD}) in the (i,j)^{th} sub-matrix location consisting of the permutation matrix P_{SPREAD} raised to the F_{i,j} power (i.e. P_{SPREAD}^{F}^{_{i,j}}).

The following is one particular example of the implementation of one arrangement. In this example,

$${H}_{SEED} = [ \begin{matrix}1 & 0 & 0 & 1 & 0 & 0 \\ 1 & 1 & 0 & 1 & 1 & 0 \\ 0 & 1 & 1 & 0 & 0 & 1 \\ 0 & 0 & 1 & 0 & 1 & 1\end{matrix} ] , thus {N}_{SEED} = 6 , \\ while$$

$${P}_{SPREAD}^{1} = [ \begin{matrix}0 & 0 & 1 \\ 1 & 0 & 0 \\ 0 & 1 & 0\end{matrix} ] , thus {N}_{SPREAD} = 3 ,$$

Therefore, p=11 is the smallest prime number that satisfies the example conditions N_{SEED}+2≦p and N_{SPREAD}≦p. The interim and final exponent matrices as defined above can be:

$${E}_{TRUNCATE 2} = [ \begin{matrix}1 & 2 & 3 & 4 & 5 & 6 \\ 0 & 2 & 4 & 6 & 8 & 10 \\ ∞ & 0 & 3 & 6 & 9 & 1 \\ ∞ & ∞ & 0 & 4 & 8 & 1\end{matrix} ] and$$

$$F = [ \begin{matrix}1 & ∞ & ∞ & 4 & ∞ & ∞ \\ 0 & 2 & ∞ & 6 & 8 & ∞ \\ ∞ & 0 & 3 & ∞ & ∞ & 1 \\ ∞ & ∞ & 0 & ∞ & 8 & 1\end{matrix} ] ,$$

and the corresponding expanded LDPC matrix can be:

$$H = [ \begin{matrix}0 & 0 & 1 & 0 & 0 & 0 & 0 & 0 & 0 & 0 & 0 & 1 & 0 & 0 & 0 & 0 & 0 & 0 \\ 1 & 0 & 0 & 0 & 0 & 0 & 0 & 0 & 0 & 1 & 0 & 0 & 0 & 0 & 0 & 0 & 0 & 0 \\ 0 & 1 & 0 & 0 & 0 & 0 & 0 & 0 & 0 & 0 & 1 & 0 & 0 & 0 & 0 & 0 & 0 & 0 \\ 1 & 0 & 0 & 0 & 1 & 0 & 0 & 0 & 0 & 1 & 0 & 0 & 0 & 1 & 0 & 0 & 0 & 0 \\ 0 & 1 & 0 & 0 & 0 & 1 & 0 & 0 & 0 & 0 & 1 & 0 & 0 & 0 & 1 & 0 & 0 & 0 \\ 0 & 0 & 1 & 1 & 0 & 0 & 0 & 0 & 0 & 0 & 0 & 1 & 1 & 0 & 0 & 0 & 0 & 0 \\ 0 & 0 & 0 & 1 & 0 & 0 & 1 & 0 & 0 & 0 & 0 & 0 & 0 & 0 & 0 & 0 & 0 & 1 \\ 0 & 0 & 0 & 0 & 1 & 0 & 0 & 1 & 0 & 0 & 0 & 0 & 0 & 0 & 0 & 1 & 0 & 0 \\ 0 & 0 & 0 & 0 & 0 & 1 & 0 & 0 & 1 & 0 & 0 & 0 & 0 & 0 & 0 & 0 & 1 & 0 \\ 0 & 0 & 0 & 0 & 0 & 0 & 1 & 0 & 0 & 0 & 0 & 0 & 0 & 1 & 0 & 0 & 0 & 1 \\ 0 & 0 & 0 & 0 & 0 & 0 & 0 & 1 & 0 & 0 & 0 & 0 & 0 & 0 & 1 & 1 & 0 & 0 \\ 0 & 0 & 0 & 0 & 0 & 0 & 0 & 0 & 1 & 0 & 0 & 0 & 1 & 0 & 0 & 0 & 1 & 0\end{matrix} ] .$$

One arrangement of a method for constructing irregularly structured LDPC codes according to the present invention is depicted in FIG. 4. At step 100, an irregular “seed”” parity check matrix H_{SEED} of dimension ((N_{SEED}−K_{SEED})×N_{SEED}) can be constructed, being derived from an edge ensemble, λ_{SEED}(x) and ρ_{SEED}(x), with good asymptotic performance. In one embodiment, good asymptotic performance can be characterized by good threshold value using belief propagation decoding and good girth properties such as by having very few if no variable nodes with girth of 4. At step 110, a structured array exponent matrix can be constructed, as shown below:

$${E}_{ARRAY} = [ \begin{matrix}{E}_{1 , 1} & {E}_{1 , 2} & … & {E}_{1 , p} \\ {E}_{2 , 1} & {E}_{2 , 2} & … & {E}_{2 , p} \\ ⋮ & ⋮ & ⋰ & ⋮ \\ {E}_{p , 1} & {E}_{p , 2} & … & {E}_{p , p}\end{matrix} ] where {E}_{i , j} = ( i - 1 ) ( j - 1 ) mod p$$

This matrix can be constructed using modulo arithmetic of a number p that can be at least the column dimension of the irregular “seed” parity check matrix and the column dimension of the spreading permutation matrix. In other words, N_{SEED}≦p and N_{SPREAD}≦p.

At step 120, the structured array exponent matrix can be transformed using a transform T(E_{ARRAY}) that may perform shifts, truncations, permutations, etc. operations to construct an exponent matrix of dimension ((N_{SEED}−K_{SEED})×N_{SEED}) from E_{ARRAY}. At step 130, a final exponential matrix can be constructed,

$${F}_{FINAL} = \\ [ \begin{matrix}{F}_{1 , 1} & {F}_{1 , 2} & … & {F}_{1 , {N}_{SEED}} \\ {F}_{2 , 1} & {F}_{2 , 2} & … & {F}_{2 , {N}_{SEED}} \\ ⋮ & ⋮ & ⋰ & ⋮ \\ {F}_{( {N}_{SEED} - {K}_{SEED} ) , 1} & {F}_{( {N}_{SEED} - {K}_{SEED} ) , 2} & … & {F}_{( {N}_{SEED} - {K}_{SEED} ) , {N}_{SEED}}\end{matrix} ]$$

of dimension ((N_{SEED}−K_{SEED})×N_{SEED}) by replacing each one in H_{SEED} with the corresponding element in the transformed structured array exponent matrix T(E_{ARRAY}) and each zero in H_{SEED} with ∞. Thus, the elements of F_{FINAL} belong to the set {0, 1, . . . , p−1, ∞}.

At step 140, the expanded parity check matrix can be constructed,

$$H = \\ [ \begin{matrix}{P}_{SPREAD}^{{F}_{1 , 1}} & {P}_{SPREAD}^{{F}_{1 , 2}} & … & {P}_{SPREAD}^{{F}_{1 , {N}_{SEED}}} \\ {P}_{SPREAD}^{{F}_{2 , 1}} & {P}_{SPREAD}^{{F}_{2 , 2}} & … & {P}_{SPREAD}^{{F}_{2 , {N}_{SEED}}} \\ ⋮ & ⋮ & ⋰ & ⋮ \\ {P}_{SPREAD}^{{F}_{( {N}_{SEED} - {K}_{SEED} ) , 1}} & {P}_{SPREAD}^{{F}_{( {N}_{SEED} - {K}_{SEED} ) , 2}} & … & {P}_{SPREAD}^{{F}_{( {N}_{SEED} - {K}_{SEED} ) , {N}_{SEED}}}\end{matrix} ]$$

of dimension (N_{SPREAD}(N_{SEED}−K_{SEED}))×N_{SPREAD}N_{SEED}) that describes the expanded LDPC code with sub-matrices of dimension (N_{SPREAD}×N_{SPREAD}) in the (i, j)^{th} sub-matrix location consisting of the permutation matrix P_{SPREAD} raised to the F_{i,j} power, i.e. P_{SPREAD}^{F}^{_{i,j}}, where F_{i,j} is the matrix element in the (i,j)^{th} location of F_{FINAL}.
Modification of H

Consider a structured LDPC code as proposed V. Stolpman et al, with a seed matrix of dimensions (M_{SEED}×N_{SEED}) and a spreading matrix of dimensions (N_{SPREAD}×N_{SPREAD}). Following the low-complexity encoding algorithm presented in Richardson and Urbanke, we first bring the original LDPC parity check matrix H into the following form by flipping the rows and columns of the original parity check matrix H:

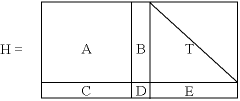

Here A, B, C, D, E, T are sparse matrices and in addition, sub-matrix T has the following lower triangular form:

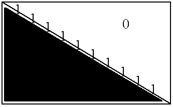

Since the H matrices in consideration are structured, the constituent sub-matrices are also structured and it is easy to show that these matrices have the following dimensions:
A: ((M_{SEED}−1)*N_{SPREAD}×(N_{SEED}−M_{SEED})*N_{SPREAD})
B: ((M_{SEED}−1)*N_{SPREAD}×N_{SPREAD})
T: ((M_{SEED}−1)*N_{SPREAD}×(M_{SEED}−1)*N_{SPREAD})
C: (N_{SPREAD}×(N_{SEED}−M_{SEED})*N_{SPREAD})
D: (N_{SPREAD}×N_{SPREAD})
E: (N_{SPREAD}×(M_{SEED}−1)*N_{SPREAD})

Pre-multiplication of H by the matrix

$$( \begin{matrix}I & 0 \\ - {ET}^{- 1} & I\end{matrix} )$$

results in the matrix

$$( \begin{matrix}\begin{matrix} & A & & & & B & & & T\end{matrix} \\ - {ET}^{- 1} A + C - {ET}^{- 1} B + D 0\end{matrix} ) ,$$

which, by definition, must also contain any valid codeword in its null space. For the ease of notation, we represent any codeword x as x=(s, p₁, p₂) where s is the systematic part, parity part p₁ has length N_{SPREAD} and parity part p₂ has length ((M_{SEED}−1)*N_{SPREAD}).

Based upon the above definitions, it was shown by Richardson and Urbanke that p₁ and p₂ can be computed as follows:
p₁^{T}=−φ⁻¹(−ET⁻¹A+C)s^{T}, and
p₂^{T}=−T⁻¹(As^{T}+Bp₁^{T}),
where φ=−ET⁻¹B+D.

In the above encoding procedure, the most computation intensive procedures are the computation of φ⁻¹ and T⁻¹. In what follows, we address this problem by devising simple algorithms which enable computation of the above matrix inverses in low complexity.

Efficient Computation of T⁻¹

It can be shown that F_{T}, the exponent matrix corresponding to the matrix T, has the following form (ignoring the modulo N_{SPREAD} operation):

$${F}_{T} = ( \begin{matrix}0 & - ∞ & - ∞ & ⋯ & - ∞ \\ ( {M}_{SEED} - 1 ) & 0 & - ∞ & ⋯ & - ∞ \\ - ∞ & ⋰ & 0 & ⋰ & ⋮ \\ ⋮ & ⋰ & 3 & 0 & - ∞ \\ - ∞ & ⋯ & - ∞ & 2 & 0\end{matrix} )$$

The above matrix has zeros along it's main diagonal, the entries [M_{SEED}−1, M_{SEED}−2, . . . , 3, 2] along the lower sub-diagonal and the remaining entries equal negative infinity.

To construct T⁻¹ from F_{T}, we first compute F_{T}^{inv}, the exponent form representation of the matrix T⁻¹ and then construct T⁻¹ from F_{T}^{inv}. The algorithm presented below describes this procedure:
1. Construct a “skeleton” matrix as follows:

$${F}_{T}^{inv} = \begin{matrix}0 & - ∞ & - ∞ & … & - ∞ \\ {M}_{SEED} - 1 & 0 & - ∞ & … & - ∞ \\ & {M}_{SEED} - 2 & 0 & ⋰ & ⋮ \\ & & ⋰ & ⋰ & - ∞ \\ & & & 3 & 0\end{matrix}$$
2. Begin populating this matrix column-wise, starting from the top most unspecified element of each column, going till the last element as follows:
   [F_{T}^{inv}]_{i,j}=[F_{T}^{inv}]_{i-1,j}+[F_{T}^{inv}]_{i,i-1};
   j=1, 2, . . . , M_{SEED}−3, i=j+2, j+3, . . . , M_{SEED}−1
   i.e. each unspecified element of F_{T}^{inv} is obtained by adding the element immediately above it the same column and the element in the same row, along the lower sub-diagonal.
3. Perform modulo N_{SPREAD operation on F}_{T}^{inv} and construct T⁻¹ from this exponent matrix.

Example: M_{SEED}=12, say. For this example, matrix F_{T} is given as:

$${F}_{T} = \begin{matrix}0 & - ∞ & … & & - ∞ \\ 11 & 0 & - ∞ & & ⋮ \\ - ∞ & ⋰ & 0 & ⋰ & \\ ⋮ & ⋰ & 3 & 0 & - ∞ \\ - ∞ & … & - ∞ & 2 & 0\end{matrix}$$

Based upon F_{T}, we construct T⁻¹ as follows:
1. Construct the Skeleton Matrix

$${F}_{T}^{inv} = \begin{matrix}0 & - ∞ & … & & - ∞ \\ 11 & 0 & - ∞ & & ⋮ \\ & & 0 & ⋰ & \\ & & 3 & 0 & - ∞ \\ & & & 2 & 0\end{matrix}$$
2. Populate the skeleton matrix

$${F}_{T}^{inv} = \begin{matrix}0 & - ∞ & … & & & - ∞ \\ 11 & 0 & - ∞ & & & ⋮ \\ 11 + 10 = 21 & 10 & 0 & ⋰ & & \\ 21 + 9 = 30 & 10 + 9 = 19 & 9 & ⋰ & & \\ ⋮ & ⋮ & & ⋰ & 0 & - ∞ \\ 65 & 54 & … & 5 & 2 & 0\end{matrix}$$
3. Perform modulo N_{SPREAD operation on F}_{T}^{inv} and construct T⁻¹ from this exponent matrix.

NOTE: It should be noted that the values in the lower sub-diagonal need not be in an order, e.g. [M_{SEED}−1, M_{SEED}−2, 3, 2]. The exponent entries (ε[0, M_{SEED}−1]) can be in any arbitrary order in the lower sub-diagonal. However, the illustration above is for a particular method of code-construction described in V. Stolpman et al.

Efficient Computation of φ, φ⁻¹

Matrix φ is defined by Richardson and Urbanke as φ=−ET⁻¹B+D. In general, one can compute φ using the constituent matrices E, T⁻¹, B, D and then invert this matrix to derive φ⁻¹. However, computation of parity bits is simplified greatly if we can guarantee φ to be a permutation matrix. In their current form, the parity check matrices do not provide this guarantee. Therefore, we wish to modify the H matrix (and thereby propose new LDPC codes) such that without compromising the error correcting performance of the code, φ is guaranteed to be a permutation matrix. We achieve this goal by modifying the matrix H in V. Stolpman et al such that ET⁻¹B is the null matrix.

To be able to achieve the above goal, we first note that the matrices E, B have a regular structure as follows:
1. E=[0, . . . , 0, E₁], where E₁ is a permutation matrix derived by circularly shifting columns of the spreading matrix, P_{SPREAD}, and 0 is the null matrix of dimensions (N_{SPREAD}×N_{SPREAD}). Equivalently, in exponent form E can be expressed as F_{E}=[−∞, . . . , −∞, e₁] where e₁ denotes the circular shift on P_{SPREAD}.
2. B=[B₁, 0, . . . , 0, B_{K}, 0, . . . 0]^{T} where B₁, B_{K} are once again permutation matrices and 0 is the null matrix of dimension (N_{SPREAD}×N_{SPREAD}). Equivalently, in exponent form B can be expressed as F_{B}^{T}=[b₁, −∞, . . . , −∞, bₖ, −∞, . . . , −∞]^{T}. Here b₁, bₖ denote the rotation on P_{SPREAD} as before.

Based upon the above observations, ET⁻¹B can be expressed in exponent form as

$${ET}^{- 1} B = {P}_{spread}^{{e}_{1}} ( {P}_{spread}^{{b}_{1} + {[ {F}_{T}^{inv} ]}_{{M}_{seed} - 1 , 1}} + {P}_{spread}^{{b}_{k} + {[ {F}_{T}^{inv} ]}_{{M}_{seed} - 1 , k}} )$$

Modifying the H matrix such that bₖ=b₁+└F_{T}^{inv}┘_{M}_{_{seed}}_{-1,1}−└F_{T}^{inv}┘_{M}_{_{seed}}_{-1,k} will result in ET⁻¹B being equal to the null matrix and hence in φ being equal to the permutation matrix D. In this form, it becomes trivial to invert φ and to perform matrix operations involving computation of p₁ using φ⁻¹.

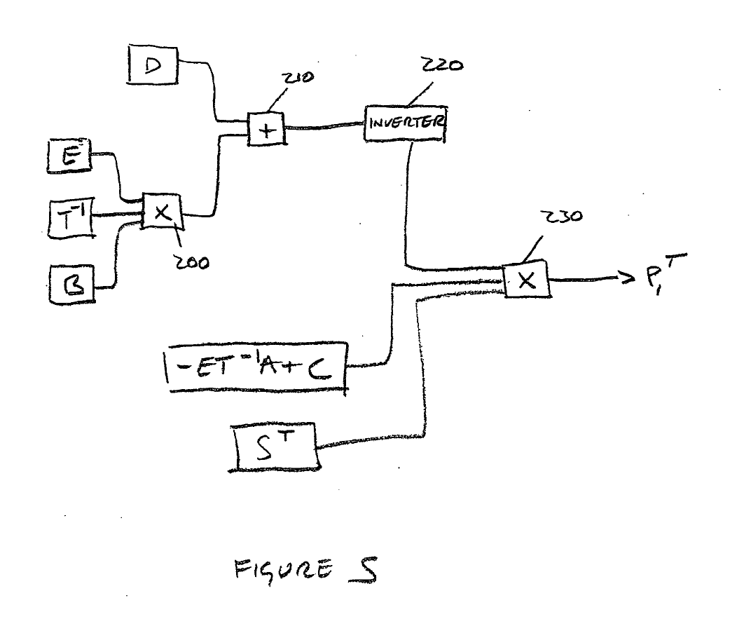

FIG. 5 is a schematic diagram of a transmitter which encodes and transmits data according to the algorithm disclosed by Richardson and Urbanke. In this arrangement, in order to calculate p₁^{T}, ASIC gates 200, 210 must be provided in order to perform the multiplication and addition required to generate φ, prior to inversion (by inverter 220) and multiplication (by multiplier 230) with (ET⁻¹A+C) and s^{T} in accordance with the equation p₁^{T}=−φ⁻¹ (−ET⁻¹A+C)s^{T} where φ=−ET⁻¹B+D.

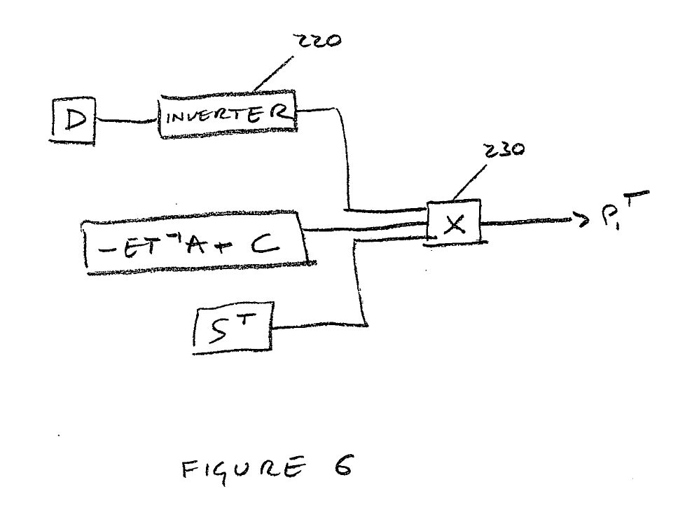

FIG. 6 is a schematic diagram of a transmitter according to an embodiment of the present invention. The transmitter encodes and transmits data according to the new algorithm in which ET⁻¹B is equal to the null matrix whereby φ is equal to D. As such, the ASIC gates 200, 210 required to generate φ in the arrangement shown in FIG. 5 are no longer required, and p₁^{T} is generated according to the formula p₁^{T}=−D⁻¹ (−ET⁻¹A+C)s^{T}. This arrangement is reduced in complexity compared to the arrangement shown in FIG. 5 in terms of both hardware and software. Furthermore, the transmitter is more efficient at encoding and transmitting data at high rates with low errors as fewer operations are required in order to generate the codewords.

Results

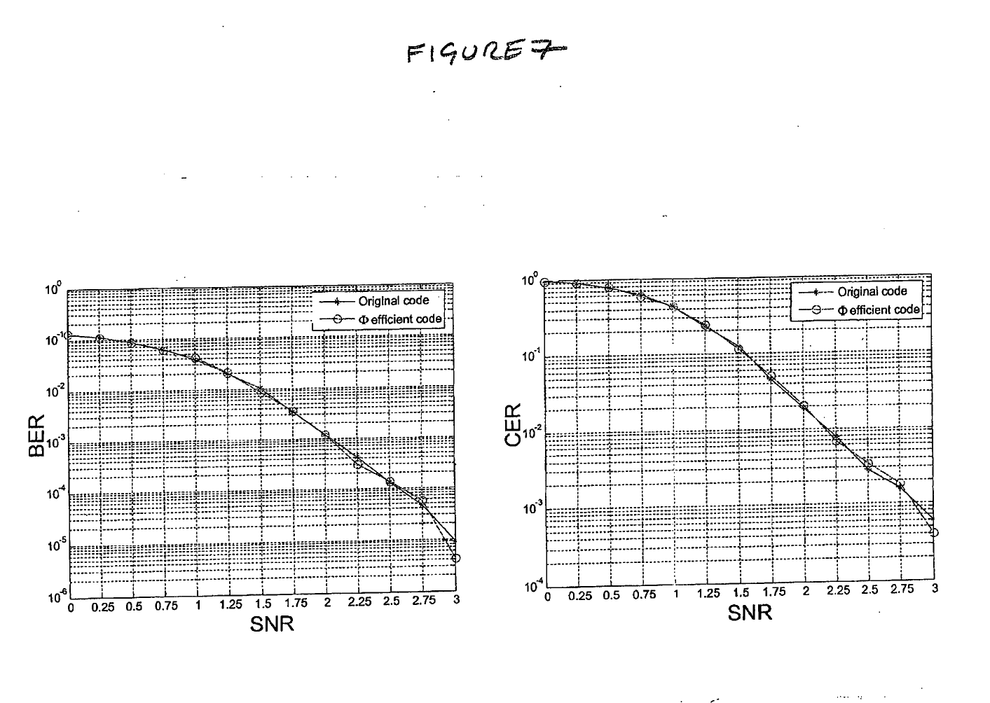

FIG. 7 presents the comparative bit error rate (BER) performance and codeword error rate (CER) performance in AWGN environment of the original LDPC code and the modified LDPC code such that φ is a permutation matrix for the LDPC code of block length 72 bytes and rate ½.

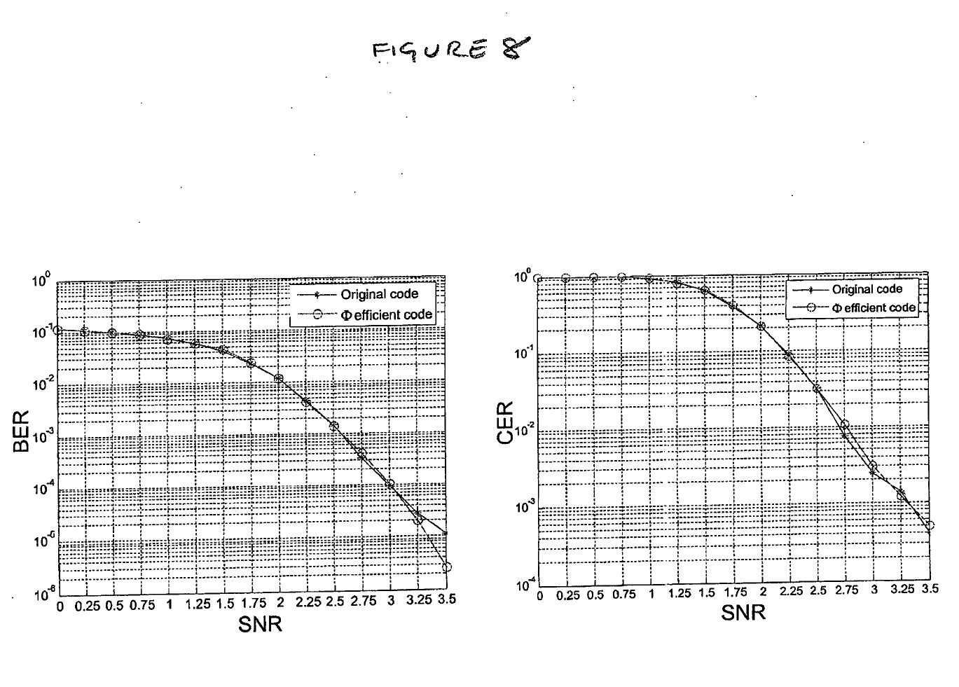

FIG. 8 presents the comparative BER and CER performance in AWGN environment of the original LDPC code and the modified LDPC code such that φ is a permutation matrix for the LDPC code of block length 72 bytes and rate ⅔.

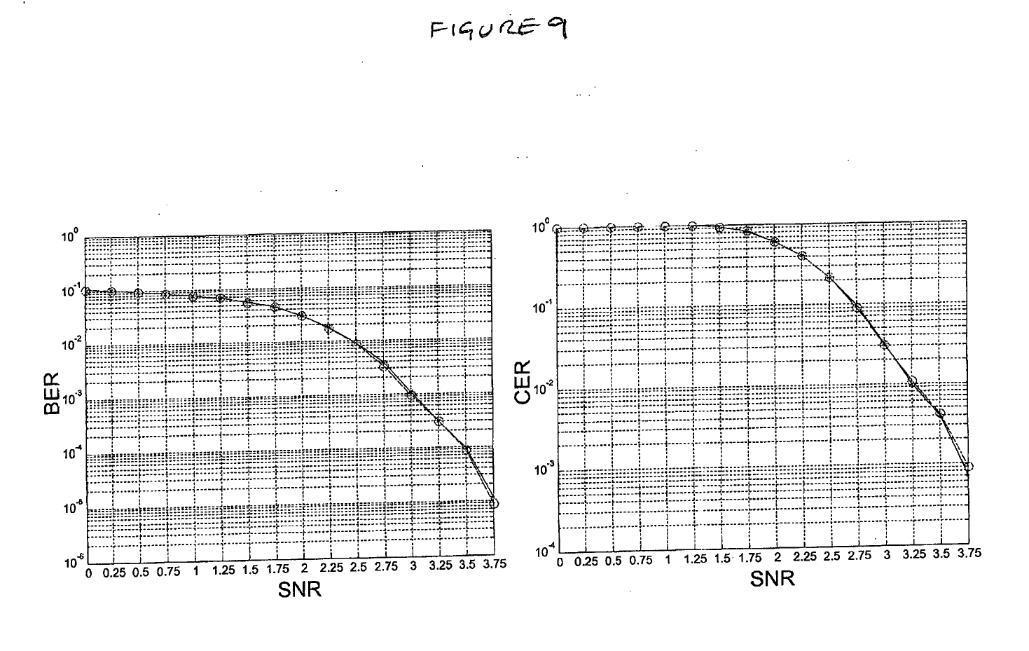

FIG. 9 presents the comparative BER and CER performance in AWGN environment of the original LDPC code and the modified LDPC code such that φ is a permutation matrix for the LDPC code of block length 72 bytes and rate ¾.

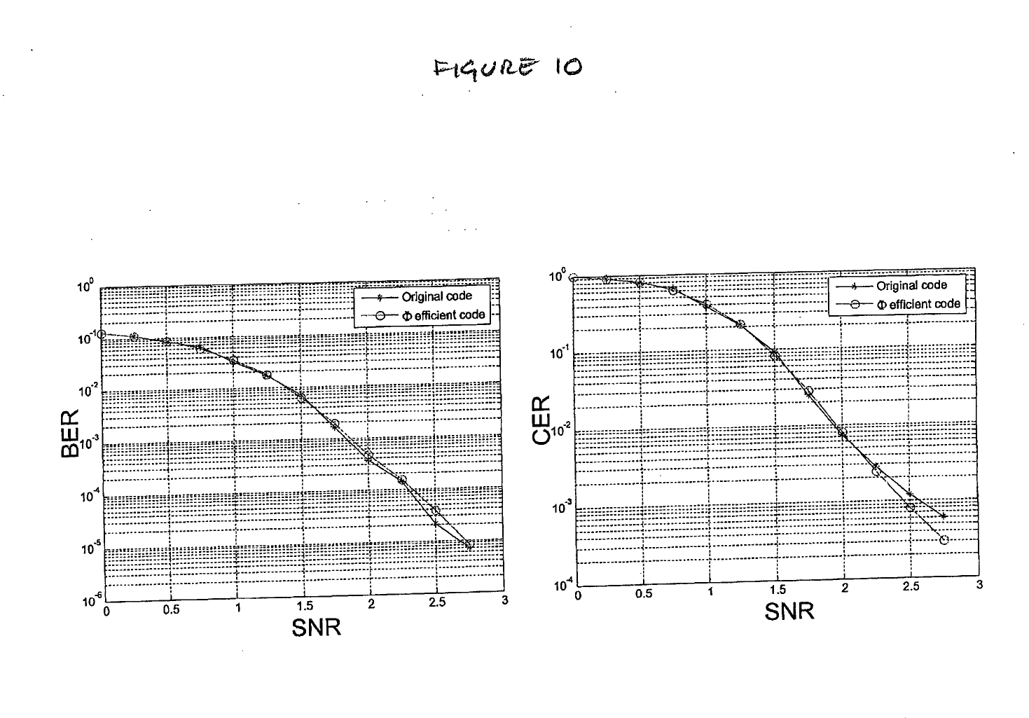

FIG. 10 presents the comparative BER and CER performance in AWGN environment of the original LDPC code and the modified LDPC code such that φ is a permutation matrix for the LDPC code of block length 90 bytes and rate ½.

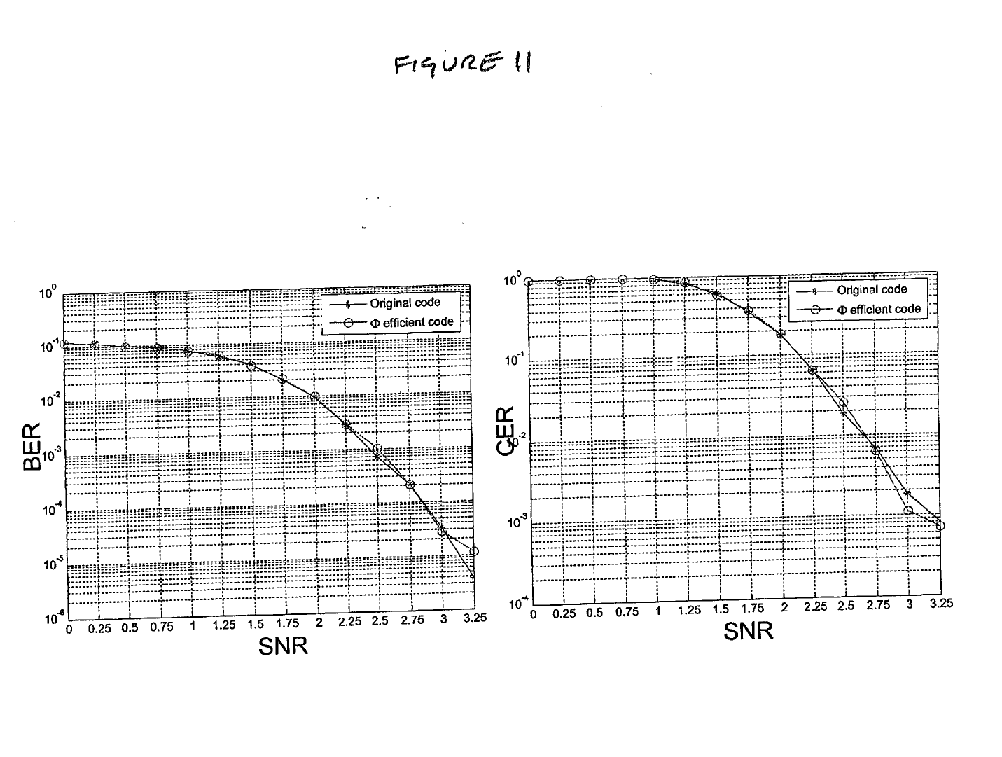

FIG. 11 presents the comparative BER and CER performance in AWGN environment of the original LDPC code and the modified LDPC code such that φ is a permutation matrix for the LDPC code of block length 90 bytes and rate ⅔.

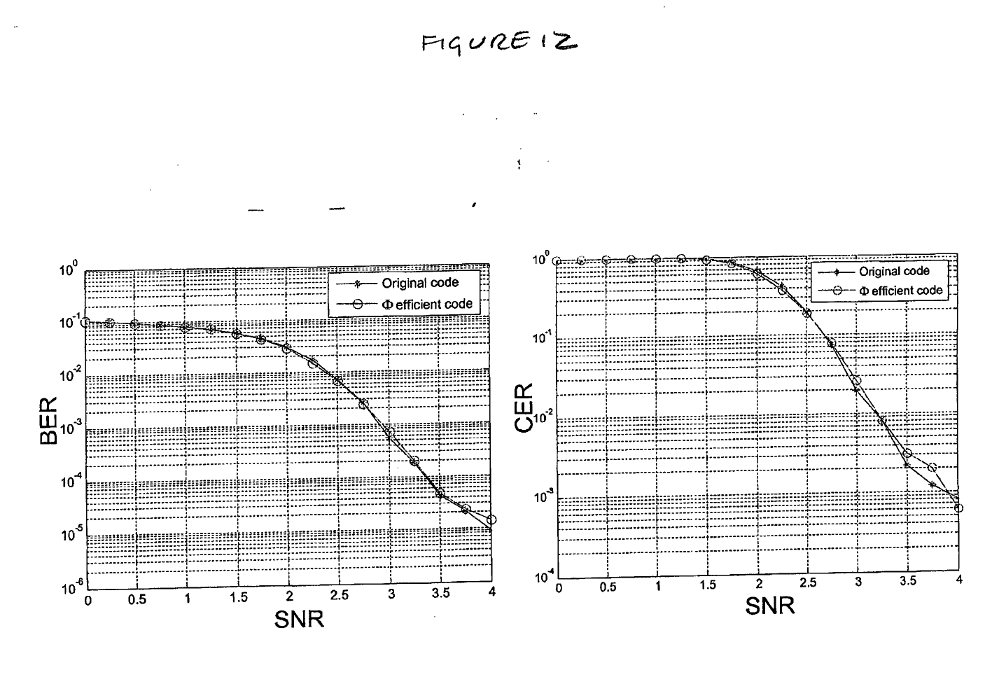

FIG. 12 presents the comparative BER and CER performance in AWGN environment of the original LDPC code and the modified LDPC code such that φ is a permutation matrix for the LDPC code of block length 90 bytes and rate ¾.

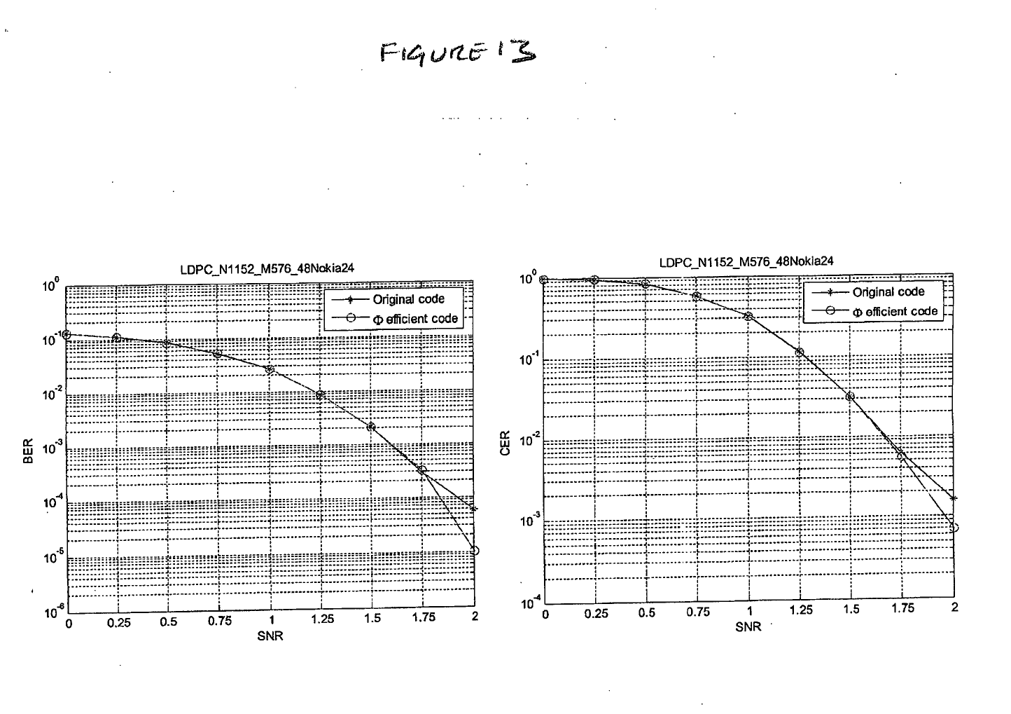

FIG. 13 presents the comparative BER and CER performance in AWGN environment of the original LDPC code and the modified LDPC code such that φ is a permutation matrix for the LDPC code of block length 144 bytes and rate ½.

The foregoing description of embodiments of the present invention have been presented for purposes of illustration and description. It is not intended to be exhaustive or to limit the present invention to the precise form disclosed, and modifications and variations are possible in light of the above teachings or may be acquired from practice of the present invention. The embodiments were chosen and described in order to explain the principles of the present invention and its practical application to enable one skilled in the art to utilize the present invention in various embodiments and with various modifications as are suited to the particular use contemplated. For example, it will be understood that a parity check matrix which, in expanded form, can be represented by the matrix H, can also be represented by the matrix H″ having the general structure

$$( \begin{matrix}{E}^{′} & {D}^{′} & {C}^{′} \\ {T}^{′} & {B}^{′} & {A}^{′}\end{matrix} )$$

where H″ can be achieved by reversing the elements of each row, and then reversing the elements of each column of H. In one such arrangement, T′ is upper triangular. The matrix dimensions may be expressed as E′=[E′₁, 0, . . . , 0] and B′=[0, . . . , 0, B′_{K}, 0, . . . , 0, B′₁]. The major equations and overall interpretation do not change except that systematic and parity bits swap their respective position. The appended claims are intended to cover the aforementioned variations.

1. A transmitter for a communications network, the transmitter comprising:
receiving means for receiving data;
accessing means for accessing a parity check code;
generating means for generating encoded data including an error correction codeword using the data and the parity check code; and
transmitting means for transmitting the encoded data and the error correction codeword,
wherein the parity check code comprises a parity check matrix which, in expanded form, can be represented by the matrix H having the general structure
$$( \begin{matrix}A & B & T \\ C & D & E\end{matrix} )$$
wherein A, B, T, C, D and E represent sub-matrices, ET⁻¹B being equal to the null matrix, the generating means comprising summing circuitry arranged to receive matrix elements ET⁻¹A and C to generate a sum, and matrix multiplication circuitry for receiving the sum, a matrix element D⁻¹ and a matrix s^{T} comprising the data, the matrix multiplication circuitry being operable to generate a parity part p₁^{T} of the error correction codeword according to the formula
p₁^{T}=−D⁻¹(−ET⁻¹A+C)s^{T}.

2. A transmitter according to claim 1, wherein the generating means is adapted to further generate a parity part p₂^{T} of the error correction codeword according to the formula
p₂^{T}=−T⁻¹(As^{T}+Bp₁^{T}).

3. A transmitter according to claim 1, comprising a storage means including the parity check code, and wherein the accessing means is adapted to access the parity check code which is pre-stored in the storage means.

4. A transmitter according to claim 3, comprising a processor and a memory unit operative connected to the processor, the storage unit including the storage means and the processor including the generating means.

5. A transmitter according to claim 1, wherein the accessing means is adapted to generate the parity check code.

6. A transmitter according to claim 1, wherein the transmitting means is adapted to transmit the data and codeword according to one or more of Code Division Multiple Access (CDMA), Global System for Mobile Communications (GSM), Universal Mobile Telecommunications System (UMTS), Time Division Multiple Access (TDMA), Frequency Division Multiple Access (FDMA), Transmission Control Protocol/Internet Protocol (TCP/IP), Short Messaging Service (SMS), Multimedia Messaging Service (MMS), e-mail, Instant Messaging Service (IMS), Bluetooth, and IEEE 802.11.

7. A transmitter according to claim 1, wherein H has the dimensions m×n, A is (m−g)×(n−m), B is (m−g)×g, T is (m−g)(m−g), C is g×(n−m), D is g×g, and E is g×(m−g).

8. A transmitter according to claim 7, wherein p₁ has length g.

9. A transmitter according to claim 2, wherein p₂ has length m−g.

10. A transmitter according to claim 1, wherein all matrices A to E are sparse.

11. A transmitter according to claim 1, wherein T is lower triangular with ones along the diagonal.

12. A transmitter according to claim 1, wherein D is a permutation matrix.

13. A transmitter according to claim 1, wherein E is a permutation matrix.

14. A transmitter according to claim 1, the parity check code comprises a seed matrix H_{SEED} and a spreading matrix P_{SPREAD}, the accessing means being arranged to form the parity check matrix H by expanding the seed matrix H_{SEED} using the spreading matrix P_{SPREAD}.

15. A transmitter according to claim 14, wherein H_{SEED} has dimensions M_{SEED}×N_{SEED}, P_{SPREAD} has dimensions N_{SPREAD}×N_{SPREAD}, and wherein A, B, T, C, D and E have the following dimensions:
A: ((M_{SEED}−1)*N_{SPREAD}×(N_{SEED}−M_{SEED})*N_{SPREAD})
B: ((M_{SEED}−1)*N_{SPREAD}×N_{SPREAD})
T: ((M_{SEED}−1)*N_{SPREAD}×(M_{SEED}−1)*N_{SPREAD})
C: (N_{SPREAD}×(N_{SEED}−M_{SEED})*N_{SPREAD})
D: (N_{SPREAD}×N_{SPREAD})
E: (N_{SPREAD}×(M_{SEED}−1)*N_{SPREAD})

16. A transmitter according to claim 15, wherein p₁ has length N_{SPREAD}

17. A transmitter according to claim 2, wherein p₂ has length (M_{SEED}−1)*N_{SPREAD}.

18. A transmitter according to claim 15, wherein F_{T}, the exponent matrix corresponding to T, has the following form:
$${F}_{T} = ( \begin{matrix}0 & - ∞ & - ∞ & ⋯ & - ∞ \\ ( {M}_{SEED} - 1 ) & 0 & - ∞ & ⋯ & - ∞ \\ - ∞ & ⋰ & 0 & ⋰ & ⋮ \\ ⋮ & ⋰ & 3 & 0 & - ∞ \\ - ∞ & ⋯ & - ∞ & 2 & 0\end{matrix} )$$
wherein T⁻¹ is calculable from F_{T}, by first computing F_{T}^{inv}, the exponent form representation of the matrix T⁻¹, where
[F_{T}^{inv}]_{i,j}=[F_{T}^{inv}]_{i-1,j}+[F_{T}^{inv}]_{i,i-1};
j=1, 2, . . . , M_{SEED}−3, i=j+2, j+3, . . . , M_{SEED}−1
and then constructing T⁻¹ from F_{T}^{inv}.

19. A transmitter according to claim 18, wherein elements in the lower sub-diagonal of F_{T}^{inv} are in any arbitrary order.

20. A transmitter according to claim 15, wherein E=[0, . . . , 0, E₁], where E₁ is a permutation matrix derived by circularly shifting columns of the spreading matrix, P_{SPREAD}, and 0 is the null matrix of dimensions (N_{SPREAD}×N_{SPREAD}).

21. A transmitter according to claim 20, wherein, in exponent form, E can be expressed as F_{E}=[−∞, . . . , −∞, e₁] where e₁ denotes circular shift on P_{SPREAD}.

22. A transmitter according to claim 15, wherein B=[B₁, 0, . . . , 0, B_{K}, 0, . . . , 0]^{T} where B₁, B_{K} are permutation matrices and 0 is the null matrix of dimension (N_{SPREAD}×N_{SPREAD}).

23. A transmitter according to claim 22, wherein, in exponent form, B can be expressed as F_{B}^{T}=[b₁, −∞, . . . , −∞, bₖ, −∞, . . . , −∞]^{T} where b₁, bₖ denote circular shift on P_{SPREAD}.

24. A transmitter according to claim 23, wherein ET⁻¹B can be expressed in exponent form as
$${ET}^{- 1} B = {P}_{spread}^{{e}_{1}} ( {P}_{spread}^{{b}_{1} + {[ {F}_{T}^{inv} ]}_{{M}_{seed} - 1 , 1}} + {P}_{spread}^{{b}_{k} + {[ {F}_{T}^{inv} ]}_{{M}_{seed} - 1 , k}} ) .$$

25. A transmitter according to claim 24, wherein H is arranged such that bₖ=b₁+└F_{T}^{inv}┘_{M}_{_{seed}}_{-1,1}−└_{T}^{inv}┘_{M}_{_{seed}}_{-1,k} resulting in ET⁻¹B being equal to the null matrix and hence in φ being equal to the D.

26. A transmitter according to claim 25, wherein φ is inverted and used to perform matrix operations involving computation of p₁ using φ⁻¹.

27. A transmitter according to claim 1, wherein the parity check matrix, in expanded form, can be represented by the matrix H″ having the general structure
$$( \begin{matrix}\begin{matrix} & A & & & & B & & & T\end{matrix} \\ - {ET}^{- 1} A + C - {ET}^{- 1} B + D 0\end{matrix} ) .$$

28. A method of transmitting data in a communications network, the method comprising the steps of:
receiving data;
accessing a parity check code;
generating encoded data including an error correction codeword using the data and the parity check code; and
transmitting the encoded data and the error correction codeword,
wherein the parity check code comprises a parity check matrix which, in expanded form, can be represented by the matrix H having the general structure
$$( \begin{matrix}A & B & T \\ C & D & E\end{matrix} )$$
wherein A, B, T, C, D and E represent sub-matrices and where ET⁻¹B is equal to the null matrix, the step of generating the error correction codeword including supplying selected elements of the matrix H to logic circuitry which includes summing circuitry for summing matrix elements ET⁻¹A and C to generate a sum and matrix multiplication circuitry for receiving the sum, the matrix element D⁻¹ and a matrix ST comprising the data thereby to generate a parity part p₁^{T} according to the formula
p₁^{T}=−D⁻¹(−ET⁻¹A+C)s^{T}.

29. A method according to claim 28, wherein the step of generating the error correction codeword further includes generating a parity part p₂^{T} according to the formula
p₂^{T}=−T⁻¹(As^{T}+Bp₁^{T}).

30. A method according to claim 28, wherein the step of accessing the parity check code comprises accessing the parity check code which is pre-stored in a memory means.

31. A method according to claim 28, wherein the step of accessing the parity check code comprises generating the parity check code.

32. A method according to claim 28, wherein the encoded data and codeword are transmitted according to one or more of Code Division Multiple Access (CDMA), Global System for Mobile Communications (GSM), Universal Mobile Telecommunications System (UMTS), Time Division Multiple Access (TDMA), Frequency Division Multiple Access (FDMA), Transmission Control Protocol/Internet Protocol (TCP/IP), Short Messaging Service (SMS), Multimedia Messaging Service (MMS), e-mail, Instant Messaging Service (IMS), Bluetooth, and IEEE 802.11.

33. A method according to claim 28, wherein H has the dimensions m×n, A is (m−g)×(n−m), B is (m−g)×g, T is (m−g)(m−g), C is g×(n−m), D is g×g, and E is g×(m−g).

34. A method according to claim 33, wherein p₁ has length g.

35. A method according to claim 29, wherein p₂ has length m−g.

36. A method according to claim 28, wherein all matrices A to E are sparse.

37. A method according to claim 28, wherein T is lower triangular with ones along the diagonal.

38. A method according to claim 28, wherein D is a permutation matrix.

39. A method according to claim 28, wherein E is a permutation matrix.

40. A method according to claim 28, the parity check code comprises a seed matrix H_{SEED} and a spreading matrix P_{SPREAD}, the step of accessing the parity check code comprising forming the parity check matrix H by expanding the seed matrix H_{SEED} using the spreading matrix P_{SPREAD}.

41. A method according to claim 40, wherein H_{SEED} has dimensions M_{SEED}×N_{SEED}, P_{SPREAD} has dimensions N_{SPREAD}×N_{SPREAD}, and wherein A, B, T, C, D and E have the following dimensions:
A: ((M_{SEED}−1)*N_{SPREAD}×(N_{SEED}−M_{SEED})*N_{SPREAD})
B: ((M_{SEED}−1)*N_{SPEAD}×N_{SPEAD})
T: ((M_{SEED}−1)*N_{SPREAD}×(M_{SEED}−1)*N_{SPREAD})
C: (N_{SPREAD}×(N_{SEED}−M_{SEED})*N_{SPREAD})
D: (N_{SPREAD}×N_{SPREAD})
E: (N_{SPREAD}×(M_{SEED}−1)*N_{SPREAD})

42. A method according to claim 41, wherein p₁ has length N_{SPREAD}

43. A method according to claim 29, wherein p₂ has length (M_{SEED}−1)*N_{SPREAD}.

44. A method according to claim 41, wherein F_{T}, the exponent matrix corresponding to T, has the following form:
$${F}_{T} = ( \begin{matrix}0 & - ∞ & - ∞ & ⋯ & - ∞ \\ ( {M}_{SEED} - 1 ) & 0 & - ∞ & ⋯ & - ∞ \\ - ∞ & ⋰ & 0 & ⋰ & ⋮ \\ ⋮ & ⋰ & 3 & 0 & - ∞ \\ - ∞ & ⋯ & - ∞ & 2 & 0\end{matrix} )$$
wherein T⁻¹ is calculable from F_{T}, by first computing F_{T}^{inv}, the exponent form representation of the matrix T⁻¹, where
[F_{T}^{inv}]_{i,j}=[F_{T}^{inv}]_{i-1,j}+[F_{T}^{inv}]_{i,i-1};
j=1, 2, . . . , M_{SEED}−3, i=j+2, j+3, . . . , M_{SEED}−1
and then constructing T⁻¹ from F_{T}^{inv}.

45. A method according to claim 44, wherein elements in the lower sub-diagonal of F_{T}^{inv} are in any arbitrary order.

46. A method according to claim 41, wherein E=[0, . . . , 0, E₁], where E₁ is a permutation matrix derived by circularly shifting columns of the spreading matrix, P_{SPREAD}, and 0 is the null matrix of dimensions (N_{SPREAD}×N_{SPREAD}).

47. A method according to claim 46, wherein, in exponent form, E can be expressed as F_{E}=[−∞, . . . , −∞, e₁] where e₁ denotes circular shift on P_{SPREAD}.

48. A method according to claim 41, wherein B=[B₁, 0, . . . , 0, B_{K}, 0, . . . , 0]^{T} where B₁, B_{K} are permutation matrices and 0 is the null matrix of dimension (N_{SPREAD}×N_{SPREAD}).

49. A method according to claim 48, wherein, in exponent form, B can be expressed as F_{B}^{T}=[b₁, −∞, . . . , −∞, bₖ, −∞, . . . , −∞]^{T} where b₁, bₖ denote circular shift on P_{SPREAD}.

50. A method according to claim 49, wherein ET⁻¹B can be expressed in exponent form as
$${ET}^{- 1} B = {P}_{spread}^{{e}_{1}} ( {P}_{spread}^{{b}_{1} + {[ {F}_{T}^{inv} ]}_{{M}_{seed} - 1 , 1}} + {P}_{spread}^{{b}_{k} + {[ {F}_{T}^{inv} ]}_{{M}_{seed} - 1 , k}} ) .$$

51. A method according to claim 50, wherein H is arranged such that bₖ=b₁+└F_{T}^{inv}┘_{M}_{_{seed}}_{-1,1}−└F_{T}^{inv}┘_{M}_{_{seed}} _{-1,k} resulting in ET⁻¹B being equal to the null matrix and hence in φ being equal to the D.

52. A method according to claim 51, wherein φ is inverted and used to perform matrix operations involving computation of p₁ using φ⁻¹.

53. A method according to claim 28, wherein the parity check matrix, in expanded form, can be represented by the matrix H′ having the general structure
$$( \begin{matrix}\begin{matrix} & A & & & & & B & & T\end{matrix} \\ - {ET}^{- 1} A + C - {ET}^{- 1} B + D 0\end{matrix} ) .$$

54. A parity check code comprising a parity check matrix which, in expanded form, can be represented by the matrix H having the general structure
$$( \begin{matrix}A & B & T \\ C & D & E\end{matrix} )$$
wherein A, B, T, C, D and E represent sub-matrices and wherein ET⁻¹B is equal to the null matrix.

55. A parity check code according to claim 54, wherein H has the dimensions m×n, A is (m−g)×(n−m), B is (m−g)×g, T is (m−g)(m−g), C is g×(n−m), D is g×g, and E is g×(m−g).

56. A parity check code according to claim 54, wherein all matrices A to E are sparse.

57. A parity check code according to claim 54, wherein T is lower triangular with ones along the diagonal.

58. A parity check code according to claim 54, wherein D is a permutation matrix.

59. A parity check code according to claim 54, wherein E is a permutation matrix.

60. A parity check code according to claim 54, wherein a codeword x comprises a system parts and parity parts p₁ and p₂, wherein
p₁^{T}=−φ⁻¹(−ET⁻¹A+C)s^{T}, and
p₂^{T}=−T⁻¹(As^{T}+Bp₁^{T}),
where φ=−ET⁻¹B+D,
ET⁻¹B being equal to the null matrix whereby φ is equal to D.

61. A parity check code according to claim 60, wherein p₁ has length g and p₂ has length m−g.

62. A parity check code according to claim 54, the code comprising a seed matrix H_{SEED} and a spreading matrix P_{SPREAD}, the parity check code being arranged to form the parity check matrix H by expanding the seed matrix H_{SEED} using the spreading matrix P_{SPREAD}.

63. A parity check code according to claim 62, wherein H_{SEED} has dimensions M_{SEED}×N_{SEED}, P_{SPREAD} has dimensions N_{SPREAD}×N_{SPREAD}, and wherein A, B, T, C, D and E have the following dimensions:
A: ((M_{SEED}−1)*N_{SPREAD}×(N_{SEED}−M_{SEED})*N_{SPREAD})
B: ((M_{SEED}−1)*N_{SPREAD}×N_{SPREAD})
T: ((M_{SEED}−1)*N_{SPREAD}×(M_{SEED}−1)*N_{SPREAD})
C: (N_{SPREAD}×(N_{SEED}−M_{SEED})*N_{SPREAD})
D: (N_{SPREAD}×N_{SPREAD})
E: (N_{SPREAD}×(M_{SEED}−1)*N_{SPREAD})

64. A parity check code according to claim 55, wherein p₁ has length N_{SPREAD} and p₂ has length (M_{SEED}−1)*N_{SPREAD}.

65. A parity check code according to claim 63, wherein F_{T}, the exponent matrix corresponding to T, has the following form:
$${F}_{T} = ( \begin{matrix}0 & - ∞ & - ∞ & ⋯ & - ∞ \\ ( {M}_{SEED} - 1 ) & 0 & - ∞ & ⋯ & - ∞ \\ - ∞ & ⋰ & 0 & ⋰ & ⋮ \\ ⋮ & ⋰ & 3 & 0 & - ∞ \\ - ∞ & ⋯ & - ∞ & 2 & 0\end{matrix} )$$
wherein T⁻¹ is calculable from F_{T}, by first computing F_{T}^{inv}, the exponent form representation of the matrix T⁻¹, where
[F_{T}^{inv}]_{i,j}=[F_{T}^{inv}]_{i-1,j}+[F_{T}^{inv}]_{i,i-1};
j=1, 2, . . . , M_{SEED}−3, i=j+2, j+3, . . . , M_{SEED}−1
and then constructing T⁻¹ from F_{T}^{inv}.

66. A parity check code according to claim 65, wherein elements in the lower sub-diagonal of F_{T}^{inv} are in any arbitrary order.

67. A parity check code according to claim 63, wherein E=[0, . . . , 0, E₁], where E₁ is a permutation matrix derived by circularly shifting columns of the spreading matrix, P_{SPREAD}, and 0 is the null matrix of dimensions (N_{SPREAD}×N_{SPREAD}).

68. A parity check code according to claim 67, wherein, in exponent form, E can be expressed as F_{E}=[−∞, . . . , −∞, e₁] where e₁ denotes circular shift on P_{SPREAD}.

69. A parity check code according to claim 63, wherein B=[B₁, 0, . . . , 0, B_{K}, 0, . . . , 0]^{T} where B₁, B_{K} are permutation matrices and 0 is the null matrix of dimension (N_{SPREAD}×N_{SPREAD}).

70. A parity check code according to claim 69, wherein, in exponent form, B can be expressed as F_{B}^{T}=[b₁, −∞, . . . , −∞, bₖ, −∞, . . . , −∞]^{T} where b₁, bₖ denote circular shift on P_{SPREAD}.

71. A parity check code according to claim 70, wherein ET⁻¹B can be expressed in exponent form as
$${ET}^{- 1} B = {P}_{spread}^{{e}_{1}} ( {P}_{spread}^{{b}_{1} + {[ {F}_{T}^{inv} ]}_{{M}_{seed} - 1 , 1}} + {P}_{spread}^{{b}_{k} + {[ {F}_{T}^{inv} ]}_{{M}_{seed} - 1 , k}} ) .$$

72. A parity check code according to claim 71, wherein H is arranged such that bₖ=b₁+└F_{T}^{inv}┘_{M}_{_{seed}}_{-1,1}−└F_{T}^{inv}┘_{M}_{_{seed}}_{-1,k} resulting in ET⁻¹B being equal to the null matrix and hence in φ being equal to the D.

73. A parity check code according to claim 72, wherein φ is inverted and used to perform matrix operations involving computation of p₁ using φ⁻¹.

74. A parity check code according to claim 54, wherein the parity check matrix, in expanded form, can be represented by the matrix H′ having the general structure
$$( \begin{matrix}\begin{matrix} & A & & & & & B & & T\end{matrix} \\ - {ET}^{- 1} A + C - {ET}^{- 1} B + D 0\end{matrix} ) .$$

75. An electronic device, comprising:
a processor; and
a memory unit operative connected to the processor and including the parity check code according to claim 54.

76. An electronic device according to claim 75, comprising a transmitter and/or a receiver, the transmitter facilitating encoding of data, and the receiver facilitating decoding of data after transmission through a channel.

77. An electronic device according to claim 75, wherein the electronic device is a mobile telephone, a combination PDA and mobile telephone, a PDA, an integrated messaging device (IMD), a desktop computer, or a notebook computer.

78. A communications system comprising a transmitter and a receiver, and including the parity check code according to claim 54 for encoding and transmitting data between the transmitter and receiver.

79. A communications system according to claim 78, comprising multiple communication devices that can communicate through a network.

80. A communications system according to claim 79, comprising one or more of a mobile telephone network, a wireless Local Area Network (LAN), a Bluetooth personal area network, an Ethernet LAN, a token ring LAN, a wide area network, the Internet.

81. A communications system according to claim 79, wherein the communication devices are adapted to communicate using one or more of Code Division Multiple Access (CDMA), Global System for Mobile Communications (GSM), Universal Mobile Telecommunications System (UMTS), Time Division Multiple Access (TDMA), Frequency Division Multiple Access (FDMA), Transmission Control Protocol/Internet Protocol (TCP/IP), Short Messaging Service (SMS), Multimedia Messaging Service (MMS), e-mail, Instant Messaging Service (IMS), Bluetooth, and IEEE 802.11.

82. A network element comprising the parity check code according to claim 54.

83. A computer program product comprising the parity check code according to claim 54.

84. A method of generating an error correction code, the method comprising:
providing a parity check matrix which, in expanded form, can be represented by the matrix H having the general structure
$$( \begin{matrix}A & B & T \\ C & D & E\end{matrix} )$$
wherein A, B, T, C, D and E represent sub-matrices; and modifying H wherein ET⁻¹B is equal to the null matrix.

85. A method of generating an error correction code according to claim 84, wherein the modification step involves pre-multiplying H by the matrix
$$( \begin{matrix}I & 0 \\ - {ET}^{- 1} & I\end{matrix} )$$
to give the matrix H′ having the general structure
$$( \begin{matrix}\begin{matrix} & A & & & & & B & & T\end{matrix} \\ - {ET}^{- 1} A + C - {ET}^{- 1} B + D 0\end{matrix} ) ;$$
and modifying the matrix H′ such that ET⁻¹B is equal to the null matrix.

86. A method of generating an error correction code according to claim 84, wherein the parity check matrix H is represented by a seed matrix H_{SEED} and a spreading matrix P_{SPREAD}, the modification step comprising circularly shifting columns of the spreading matrix P_{SPREAD} such that ET⁻¹B is equal to the null matrix.

87. A method of generating an error correction code according to claim 84, wherein T⁻¹ is constructed from a matrix F_{T} which is the exponent matrix corresponding to T, by inverting the matrix F_{T} to form a matrix F_{T}^{inv} which is the exponent form of the matrix T⁻¹, and performing a modulo N_{SPREAD operation on F}_{T}^{inv} to construct T⁻¹.

88. A method of generating an error correction code according to claim 84, wherein
$${ET}^{- 1} B = {P}_{spread}^{{e}_{1}} ( {P}_{spread}^{{b}_{1} + {[ {F}_{T}^{inv} ]}_{{M}_{seed} - 1 , 1}} + {P}_{spread}^{{b}_{k} + {[ {F}_{T}^{inv} ]}_{{M}_{seed} - 1 , k}} ) ,$$
and H is modified such that bₖ=b₁+└F_{T}^{inv}┘_{M}_{_{seed}}_{-1,1}−└F_{T}^{inv}┘_{M}_{_{seed}}_{-1,k} resulting in ET⁻¹B being equal to the null matrix, P_{SPREAD} being a spreading matrix, F_{T}^{inv} being the exponent form of the matrix T¹, and b₁, bₖ and e₁ being circular shifts on P_{SPREAD}.

89. A method of generating an error correction codeword using a parity check code according to claim 54, wherein the error correction codeword x comprises a systematic parts and parity parts p₁ and p₂, parity parts p₁ and p₂ being computed as follows:
p₁^{T}=−φ⁻¹(−ET⁻¹A+C)s^{T}, and
p₂^{T}=−T⁻¹(As^{T}+Bp₁^{T}),
where φ=−ET⁻¹B+D and ET⁻¹B is equal to the null matrix whereby φ is equal to D.

90. A communications system comprising a transmitter according to claim 1.

91. A network element comprising a transmitter according to claim 1.

92. A transmitter according to claim 1, wherein the parity check code comprises a parity check matrix which, in expanded form, is represented by the matrix H″ having the general structure
$$( \begin{matrix}{E}^{′} {D}^{′} {C}^{′} \\ {T}^{′} {B}^{′} {A}^{′}\end{matrix} )$$
where H″ can be achieved by reversing the elements of each row, and then reversing the elements of each column of matrix H.

93. A transmitter according to claim 92, wherein T″ is upper triangular.

94. A transmitter according to claim 92, wherein E′=[E′₁, 0, . . . , 0] and B′=[0, . . . , 0, B′_{K}, 0, . . . , 0, B′₁].

95. A method according to claim 28, wherein the parity check code comprises a parity check matrix which, in expanded form, is represented by the matrix H″ having the general structure
$$( \begin{matrix}{E}^{′} {D}^{′} {C}^{′} \\ {T}^{′} {B}^{′} {A}^{′}\end{matrix} )$$
where H″ can be achieved by reversing the elements of each row, and then reversing the elements of each column of matrix H.

96. A method according to claim 95, wherein T′ is upper triangular.

97. A method according to claim 95, wherein E′=[E′₁, 0, . . . , 0] and B′=[0, . . . , 0, B′_{K}, 0 . . . , 0, B′₁].

98. A parity check code according to claim 54, wherein the parity check code comprises a parity check matrix which, in expanded form, is represented by the matrix H″ having the general structure
$$( \begin{matrix}{E}^{′} {D}^{′} {C}^{′} \\ {T}^{′} {B}^{′} {A}^{′}\end{matrix} )$$
where H″ can be achieved by reversing the elements of each row, and then reversing the elements of each column of matrix H.

99. A parity check code according to claim 98, wherein T′ is upper triangular.

100. A parity check code according to claim 98, wherein E′=[E′₁0, . . . , 0] and B′=[0, . . . , 0, B′_{K}, 0, . . . , 0, B′₁].
